(19) United States
(12) Patent Application Publication
(10) Pub. No.: US 2021/0005604 A1
(43) Pub. Date: Jan. 7, 2021

(54) Nanosheet Transistor Stack

(71) Applicant: Qualcomm Incorporated, San Diego, CA (US)

(72) Inventors: Lixin GE, San Diego, CA (US); Ye LU, San Diego, CA (US); John Jianhong ZHU, San Diego, CA (US)

(21) Appl. No.: 16/918,770

(22) Filed: Jul. 1, 2020

Related U.S. Application Data
(60) Provisional application No. 62/870,453, filed on Jul. 3, 2019.

(51) Int. Cl. H01L 27/092; H01L 29/06; H01L 29/775; H01L 29/78; H01L 21/8238; H01L 21/033; H01L 29/66

(52) U.S. Cl. CPC H01L 27/0922; H01L 29/0673; H01L 29/775; H01L 29/66795; H01L 21/823821; H01L 21/823807; H01L 21/0337; H01L 29/785

(57) ABSTRACT

Methods and apparatuses for different types of non-planar transistors within a stack are presented. The apparatus includes a p-type transistor and an n-type transistor arranged in a stack vertically above a substrate, the p-type transistor and the n-type transistor being non-planar transistors. The p-type transistor includes a p-type channel and a first set of work function layer. The first set of work function layer surrounds the p-type channel. The p-type channel is configured for p-type conductivity based on the first set of work function layer. The n-type transistor includes an n-type channel and a second set of work function layer. The second set of work function layer surrounds the n-type channel. The n-type channel is configured for n-type conductivity based on the second set of work function layer. The first set of work function layer and the second set of work function layer are different.

### CLAIM OF PRIORITY UNDER 35. U.S.C. § 119

This application claims the priority benefit of U.S. Provisional Application Ser. No. 62/870,453, entitled “Nanosheet Transistor Stack” and filed on Jul. 3, 2019, which is expressly incorporated by reference herein in its entirety.

### BACKGROUND

### Field

The present disclosure relates generally to methods and apparatuses having non-planar transistor stacks and more particularly, to different types of non-planar transistors within a stack.

### Background

Emerging applications, such as artificial intelligence and 5G communication, call for ever-increasing improvement in performance and in power reduction of computing devices. One way to increase performance and to reduce power is to shrink sizes of transistors that function as brains of these computing devices. Planar transistors, however, is approaching process limit for device shrink. Accordingly, semiconductor industry is moving to non-planar transistors to continue transistor shrink. In some examples, non-planar transistors may include nanosheet and nanowire devices.

### SUMMARY

This summary identifies features of some example aspects and is not an exclusive or exhaustive description of the disclosed subject matter. Additional features and aspects are described and will become apparent to persons skilled in the art upon reading the following detailed description and viewing the drawings that form a part thereof.

An apparatus in accordance with at least one embodiment different types of non-planar transistors within a stack. The apparatus includes a p-type transistor and an n-type transistor. The p-type transistor and the n-type transistor are arranged in a stack vertically above a substrate, the p-type transistor and the n-type transistor being non-planar transistors. The p-type transistor includes a p-type channel and a first set of work function layer. The first set of work function layer surrounds the p-type channel. The p-type channel is configured for p-type conductivity based on the first set of work function layer. The n-type transistor includes an n-type channel and a second set of work function layer. The second set of work function layer surrounds the n-type channel. The n-type channel is configured for n-type conductivity based on the second set of work function layer. The first set of work function layer and the second set of work function layer are different.

A method to form different types of transistors within a stack, in accordance with at least one embodiment, includes forming multiple channel layers on a substrate and forming a plurality of channels within a stack on the substrate, the multiple channels being non-planar. The method further includes forming a mask layer; forming at least one work function layer; and forming different types of transistors within the stack by the mask layer masking the at least one work function layer from a portion of the plurality of channels.

### BRIEF DESCRIPTION OF THE DRAWINGS

Various aspects of apparatus and methods will now be presented in the detailed description by way of example, and not by way of limitation, with reference to the accompanying drawings, wherein:

FIG. 1 illustrates components of an apparatus incorporating having nanosheet transistors, in accordance with certain aspects of the present disclosure.

FIG. 2 illustrates a cross section view of an embodiment of different types of nanosheet transistors arranged in a stack vertically above a substrate, in accordance with certain aspects of the present disclosure.

FIG. 3 illustrates a cross section view of another embodiment of different types of nanosheet transistors arranged in a stack vertically above a substrate, in accordance with certain aspects of the present disclosure.

FIGS. 4A-4E illustrate various stages of forming different types of transistors within a stack, in accordance with certain aspects of the present disclosure.

FIG. 5 illustrates a method to form different types of transistors within a stack, in accordance with certain aspects of the present disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for providing a thorough understanding of various concepts. However, it will be apparent to those skilled in the art that these concepts may be practiced without these specific details. In some instances, well known structures and components are shown in block diagram form to avoid obscuring such concepts.

As used herein, the term “coupled to” in the various tenses of the verb “couple” may mean that element A is directly connected to element B or that other elements may be connected between elements A and B (i.e., that element A is indirectly connected with element B), to operate certain intended functions. In the case of electrical components, the term “coupled to” may also be used herein to mean that a wire, trace, or other electrically conductive material is used to electrically connect elements A and B (and any components electrically connected therebetween). In some examples, the term “coupled to” mean a transfer of electrical energy between elements A and B, to operate certain intended functions.

In some examples, the term “electrically connected” mean having an electric current or configurable to having an electric current flowing between the elements A and B. For example, the elements A and B may be connected via resistors, transistors, or an inductor, in addition to a wire, trace, or other electrically conductive material and components. Furthermore, for radio frequency functions, the elements A and B may be “electrically connected” via a capacitor or other components.

The terms “first,” “second,” “third,” etc. are employed for ease of reference and may not carry substantive meanings. Likewise, names for components/modules may be adopted for ease of reference and might not limit the components/modules. Modules and components presented in the disclosure may be implemented in hardware or a combination of hardware and software.

The term “bus system” may provide that elements coupled to the “bus system” may exchange information therebetween, directly or indirectly. In such fashion, the “bus system” may encompass multiple physical connections as well as intervening stages such as buffers, latches, registers, etc.

The term “disposed on,” “on” (when used to described physical relationship), “affixed on” may indicate the elements being physically connected, either directly (no intervening elements therebetween) or indirectly (at least one additional element therebetween). Thus, in some examples, “disposed on” may indicate directly disposed on; “on” may indicate directly on; and/or “affixed” may indicate directly affixed.

The term “a stack” or references thereto may denote a single stack in this disclosure. The stack may be a unitary structure. For example, the stack might not be an assembly of individual parts. The term “surround,” as in, for example, a gate electrode surrounding a transistor channel (hereinafter “channel”), may refer to being over an outer surface of a surrounded object, directly or indirectly. In some examples, the term “surround” may denote over 50% or more of the outer surface. In some examples, the term “surround” may denote being over the surrounded object sufficiently for a gate-all-around process.

As demands for performance grow, semiconductor industry is shifting to non-planar transistors to continue device shrink to meet those demands. Non-planar transistors may have channel regions (e.g., conducting currents) in multiple dimensions and may include, for example, nanosheet and nanowire transistors. Commonly, p-type transistors and n-type transistors are formed in different stacks, each stack containing but one type of transistors. Having different types of transistors within a single stack would reduce die size and improve performance.

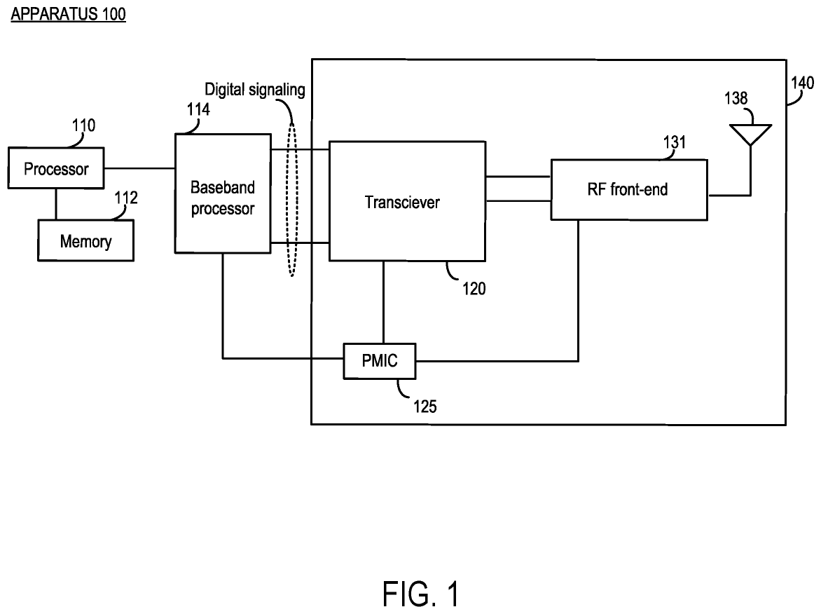

FIG. 1 illustrates components of an apparatus incorporating having nanosheet transistors, in accordance with certain aspects of the present disclosure. The apparatus 100 may, for example, be one of a computing system (e.g., servers, datacenters, desktop computers), mobile computing device (e.g., laptops, cell phones, vehicles, etc.), Internet of Things device, virtual reality system, or augmented reality system and may be configured to function an user equipment or a base station. FIG. 1 illustrates the apparatus 100 incorporating at least one processor 110, a memory 112, a baseband processor 114, and an antenna module 140. The baseband processor 114 is coupled to the memory 112 and may be configured to perform a computing function (e.g., graphic, displaying function, or sensing, etc., for the computing system, mobile computing device, Internet of Things device, virtual reality system, or augmented reality system) with the memory 112. For example, the memory 112 may store an instruction or data for the computing function.

The at least one processor 110 is coupled to the baseband processor 114 and to the antenna module 140 to perform, for example, wireless communications. The baseband processor 114 is coupled to the antenna module 140 and may be configured to operate RF communicating functions via wireless communication networks. For example, the baseband processor 114 may be configured to formulate logic layers and physical layers signaling based on protocols of the wireless communication networks (e.g., 5G, LTE, Wi-Fi, Bluetooth, etc.) in digital domain. The baseband processor 114 may be configured to output to (or to input from) the antenna module 140 for transmission (or receiving) of RF signaling via the antenna module 140.

The antenna module 140 includes an antenna 138, a transceiver 120, a power management integrated circuit (PMIC) 125, and a radio frequency (RF) front-end 131. The antenna module 140, in some examples, may include an envelope-tracking circuit (not shown). the antenna module 140 may further include passive components (such as inductors and capacitors; not shown). These components operate to perform RF communications between the baseband processor 114 and the antenna 138.

The antenna 138 may be configured to transmit or to receive RF signals for the wireless communication networks. The antenna 138 may be, for example, patch antennas. The PMIC 125 may be configured to provide power to the transceiver 120 (and/or the RF front-end 131). The transceiver 120 may be configured to convert digital signaling from the baseband processor 114 to RF signaling in a carrier frequency for transmission by the antenna 138 and/or, to convert RF signals at the carrier frequency received from the antenna 138 into digital signaling for the baseband processor 114. FIG. 1 illustrates that the transceiver 120 receives signaling from or provide signaling to be transmitted to the antenna 138 via the RF front-end 131.

The RF front-end 131 may be configured to select and to adjust RF signals for transmission or RF signals received by the antenna 138. For example, the RF front-end 131 may switch between providing signals to and receiving signals from the antenna 138, between signaling paths in a multiple-input and multiple-output system, between different wireless communication protocols, or different frequency bands. The RF front-end 131 may further adjust RF signaling, such as signal amplification and filtering.

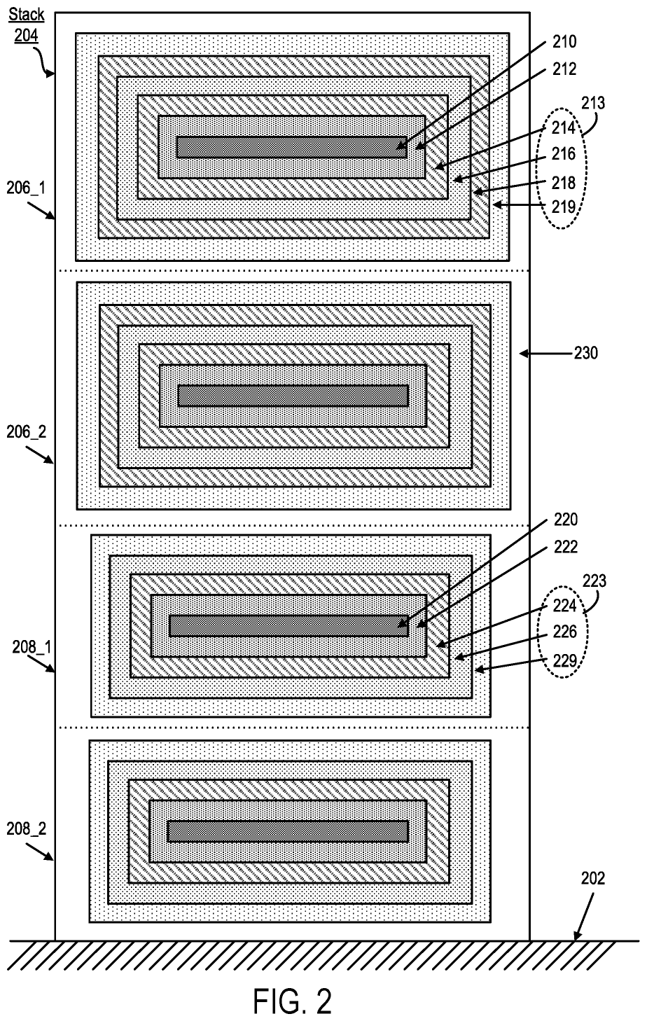

FIG. 2 illustrates a cross section view of an embodiment of different types of nanosheet transistors arranged in a stack vertically above a substrate, in accordance with certain aspects of the present disclosure. A stack 204 is disposed on a substrate 202. The substrate 202 may be, for example, silicon or an insulator. The stack 204 includes p-type transistors 206_1 and 206_2 and n-type transistors 208_1 and 208_2 arranged vertically above the substrate 202.

Nanosheet transistors, such as the p-type transistors 206_1, 206_2 and the n-type transistors 208_1, and 208_2, each includes a sheet-like channel. For example, such channel may have a surface area larger than a height. The p-type transistor 206_1 includes a p-type channel 210 extending into or out of FIG. 2. FIG. 2 being section cross section view, source and drain regions of the transistors 206_1, 206_2, 208_1, and 208_2 are into or out of the figure and therefore, are not shown. In some examples, the p-type channel 210 may be silicon.

In some examples, the p-type transistors 206_1, 206_2 and the n-type transistors 208_1, and 208_2 are gate-all-around transistors. The p-type transistor 206_1 may include a dielectric layer 212 all around the p-type channel 210. The term “all around” may be, for example, all around in vertical and horizontal directions, with respect to the substrate 202. In some examples, the dielectric layers 212 may be high-k dielectric.

The p-type transistor 206_1 may further include a first set of work function layer 213 surrounding the p-type channel 210. In some examples, the first set of work function layer 213 may be all around the p-type channel 210. The first set of work function layer 213 may include one or multiple work function layers. Conductivity characteristics of nanosheet channels, such as polarities of threshold voltages, may be based on the one or the multiple work function layers (e.g., based on a combination of the multiple work function layers) of a set of work function layer.

For example, the one or the multiple work function layers may be configured such that a threshold voltage of a nanosheet channel is negative, and the nanosheet channel would be of p-type conductivity. For example, a negative gate-source voltage (V_{GS}) would cause the nanosheet channel of the p-type conductivity to conduct current, thereby turning on a (p-type) transistor of the nanosheet channel. Alternatively, the one or the multiple work function layers may be configured such that a threshold voltage of a nanosheet channel is positive, and the nanosheet channel would be of n-type conductivity. For example, a positive gate-source voltage (V_{GS}) would cause the nanosheet channel of the n-type conductivity to conduct current, thereby turning on a (n-type) transistor of the nanosheet channel. Alternatively, the one or the multiple work function layers may be configured such that a threshold voltage of a nanosheet channel is negative, and the nanosheet channel would be of p-type conductivity.

The first set of work function layer 213 includes a TiN layer 214, a TaN layer 216, a TiN layer 218, and a TiAl layer 219. The TiN layer 214 may surround (e.g., all around) the dielectric layer 212. The TaN layer 216 may surround (e.g., all around) the TiN layer 214. The TiN layer 218 may surround (e.g., all around) the TaN layer 216. The TiAl layer 219 may surround (e.g., all around) the TiN layer 218. The first set of work function layer 213, via a combination of the work function layers 214, 216, 218, and 219, causes the p-type channel 210 to have p-type conductivity. A gate electrode 230 surrounds (e.g., all around) the p-type channel 210 by surrounding the first set of work function layer 213. In some examples, the gate electrode 230 may be metal, such as tungsten.

The n-type transistor 208_1 includes an n-type channel 220 extending into or out of FIG. 2. FIG. 2 being section cross section view, source and drain regions of the transistors 206_1, 206_2, 208_1, and 208_2 are into or out of the figure and therefore, are not shown. In some examples, the n-type channel 220 may be silicon.

The n-type transistor 208_1 may include a dielectric layer 222 all around the n-type channel 220. The term “all around” may be, for example, all around in vertical and horizontal directions, with respect to the substrate 202. In some examples, the dielectric layer 222 may be high-k dielectric.

The n-type transistor 208_1 may further include a second set of work function layer 223 surrounding of the n-type channel 220. In some examples, the second set of work function layer 223 may be all around the n-type channel 220. The second set of work function layer 223 may include one or multiple work function layers. Conductivity characteristics of nanosheet channels, such as polarities of threshold voltages, may be based on the one or the multiple work function layers (e.g., based on a combination of the multiple work function layers) of a set of work function layer. The first set of work function layer 213 and the second set of work function layer 223 are different, having at least one different layer therebetween.

The second set of work function layer 223 may include a TiN layer 224, a TaN layer 226, and a TiAl layer 229. The TiN layer 224 may surround (e.g., all around) the dielectric layer 222. The TaN layer 226 may surround (e.g., all around) the TiN layer 224. The TiAl layer 229 may surround (e.g., all around) the TaN layer 226. The second set of work function layer 223, via a combination of the work function layers 224, 226, and 229, causes the n-type channel 220 to have n-type conductivity. The gate electrode 230 surrounds (e.g., all around) the n-type channel 220 by surrounding the first set of work function layer 223. In some examples, the gate electrode 230 may be metal, such as tungsten.

As presented with FIG. 2, the p-type transistors 206_1, 206_2 and the n-type transistors 208_1, 208_2 are arranged in the stack 204 vertically above the substrate 202. The p-type transistors 206_1, 206_2 and the n-type transistors 208_1, 208_2 may be non-planar transistors, such as nanosheet or nanowire transistors. The p-type transistors 206_1, 206_2 and the n-type transistors 208_1, 208_2 may be gate-all-around transistors.

The p-type transistor 206_1 includes the p-type channel 210 and the first set of work function layer 213. The first set of work function layer 213 surrounds the p-type channel 210, and the p-type channel 210 is configured for p-type conductivity based on the first set of work function layer 213. The n-type transistor 208_1 includes the n-type channel 220 and a second set of work function layer 223. The second set of work function layer 223 surrounds the n-type channel 220. The n-type channel 220 is configured for n-type conductivity based on the second set of work function layer 223.

The first set of work function layer 213 and the second set of work function layer 223 are different by, for example, having at least one different work function layer or different orders of the work function layers. For example, the TiN layer 218 is part of the first set of work function layer 213 and not part of the second set of work function layer 223. In some examples, the first set of work function layer 213 and the second set of work function layer 223 share at least one common work function layers. For example, the TiN layers 2114 and 224 are a common work function layer shared by the first set of work function layer 213 and the second set of work function layer 223.

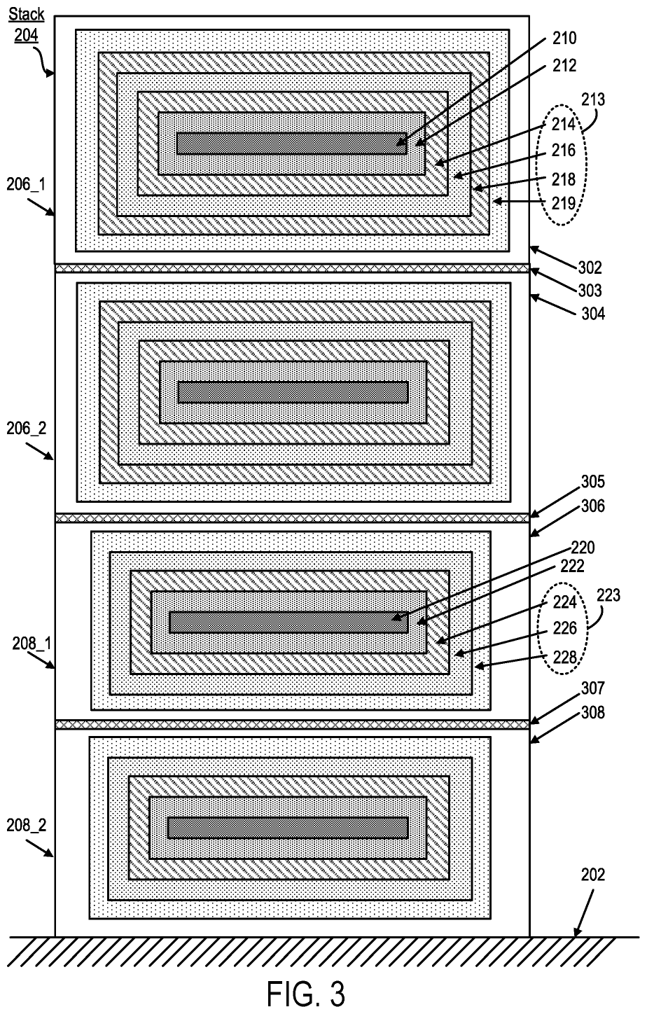

FIG. 3 illustrates a cross section view of another embodiment of different types of nanosheet transistors arranged in a stack vertically above a substrate, in accordance with certain aspects of the present disclosure. FIG. 3 illustrates the stack 204 that differs from FIG. 2 in having multiple gate electrodes in the stack 204. For example, a first gate electrode 304 surrounds (e.g., more than half of an outer surface; e.g., all around) the p-type channel 210 of the p-type transistor 206_2. A second gate electrode 306 surrounds (e.g., more than half; e.g., all around) of the n-type channel 220 of the n-type transistor 208_1. The first gate electrode 304 and the second gate electrode 306 are separated and/or insulated by an insulation layer 305. The insulation layer 305 may be, for example, silicon oxide. Being insulated by the insulation layer 305, the first gate electrode 304 and the second gate electrode 306 may be configured to operate independently. For example, the first gate electrode 304 and the second gate electrode 306 may operate at different logic levels for at least a time period.

In some examples, one of a computing system, a mobile computing system, an Internet of Things device, a virtual reality system, or an augmented reality system, such as the apparatus 100 of FIG. 1, incorporates the p-type transistors 206_1, 206_2 and the n-type transistor 208_1, 208_2.

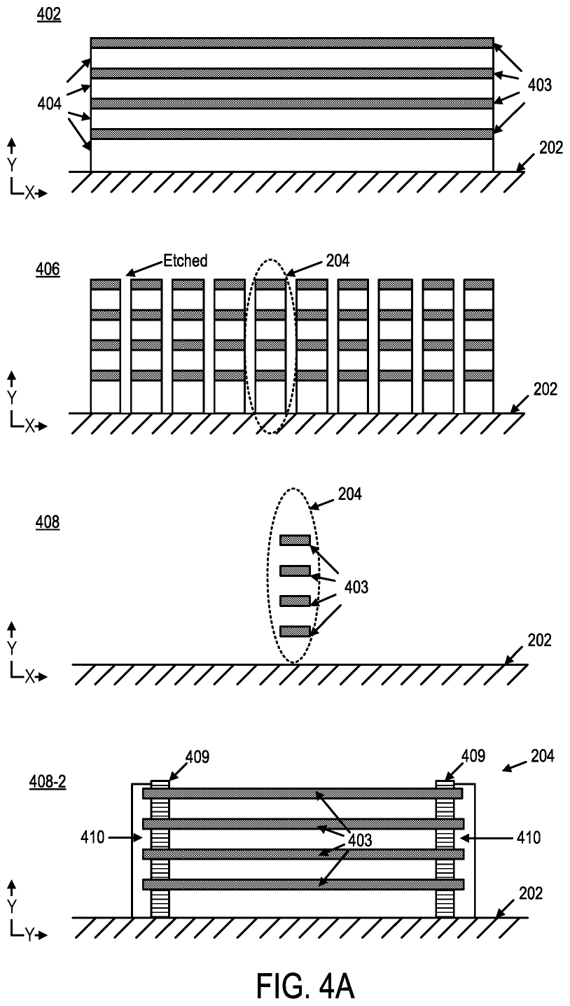

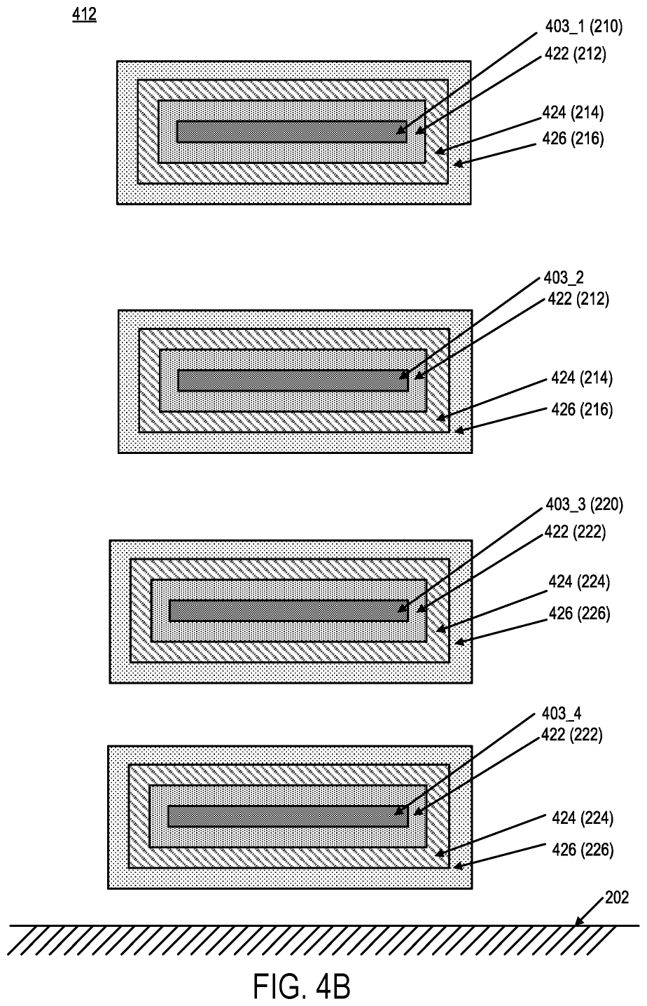

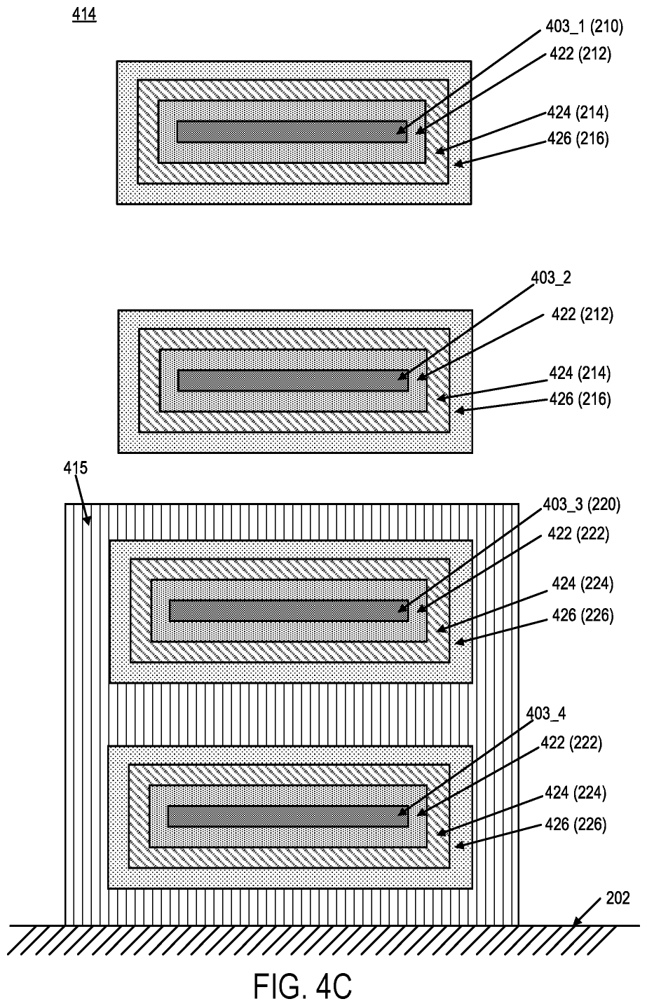

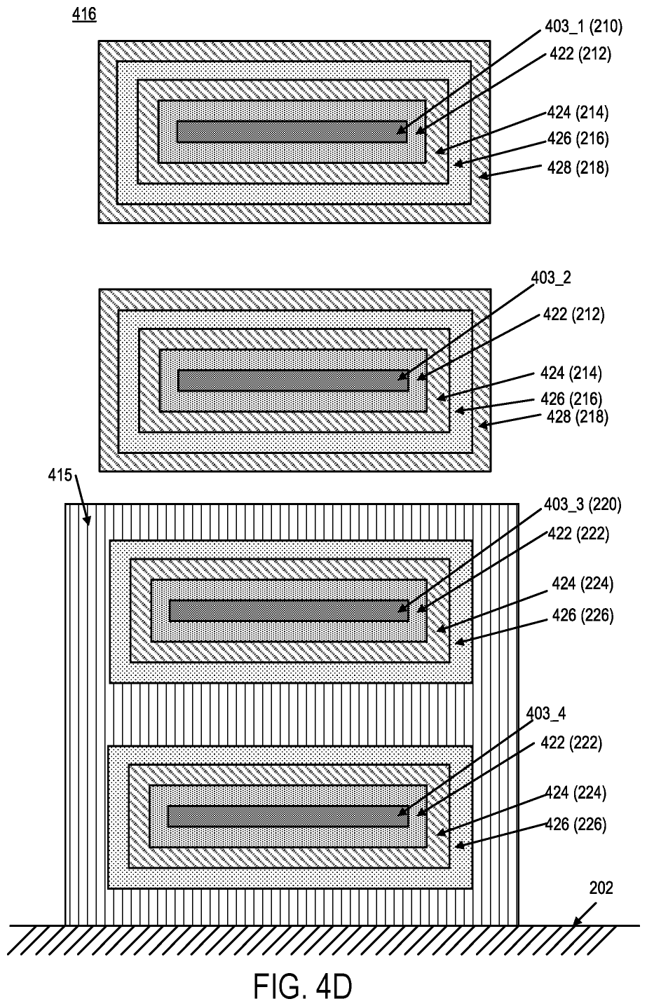

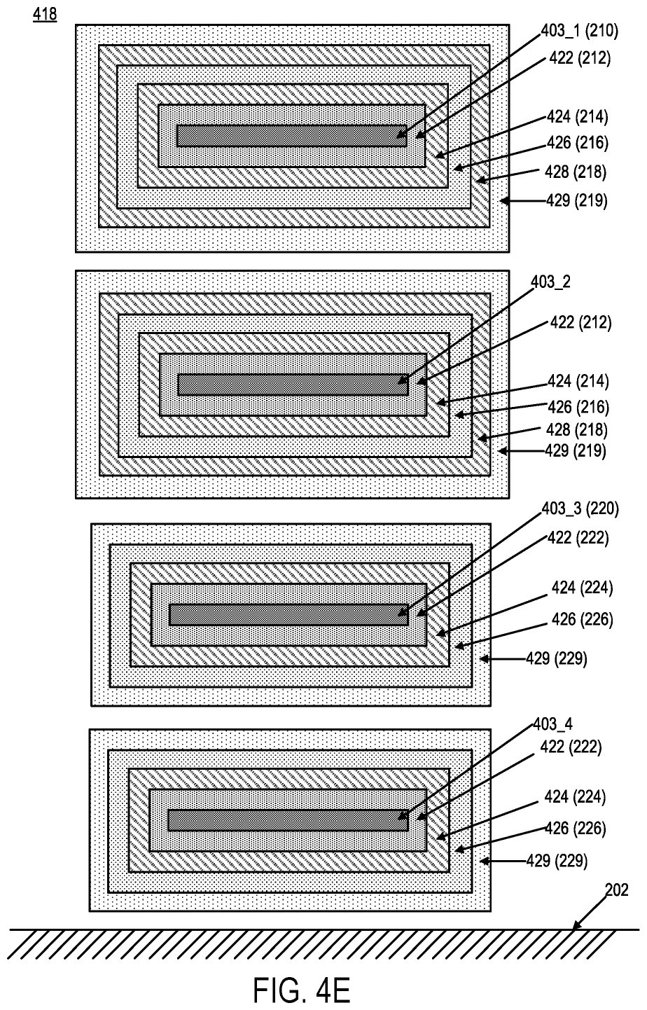

FIGS. 4A-4E illustrate various stages of forming different types of transistors within a stack, in accordance with certain aspects of the present disclosure. The different types of transistors may be, for example, p-type and n-type transistors. FIG. 4A illustrates stages 402, 406, 408, and 408-2. Stages 402, 406, and 408 are illustrated with a horizontal X-axis and a vertical Z-axis, same orientation as FIGS. 2 and 3. Stage 408-2 is the stage 408 with a horizontal Y-axis and vertical Z-axis. Stage 408-2 is a view of the stage 408 rotated by 90 degrees around the Z-axis.

At 402, multiple channel layers 403 are formed on the substrate 202 (see FIGS. 2 and 3). The channel layers 403 would become transistor channels of different types transistors in the stack. Intervening layers 404 are formed in alternate with the channel layers 403, to separate the channel layers 403. The channel layers 403 and/or the intervening layers 404 may be formed by epi growth. In some examples, the channel layers 403 may be Si, and/or the intervening layers 404 may be SiGe. The intervening layers 404 may be sacrificial layers to be removed later in the process. The channel layers 403 are non-planar. For example, the channel layers 403 may be nanowires or nanosheet (e.g., having a planar surface greater than a height thereof). Transistors incorporating the channel layers 403 would therefore be non-planar transistors.

At 406, the stack 204 having multiple channel layers 403 in a vertical direction (Z-axis) above the substrate 202 is formed. The channel layers 403 and the intervening layers 404 of the stage 402 may be etched away at various locations alone the X-axis to form various stacks, including the stack 204. In such fashion, a width of the stack 204 (and therefore the transistors within the stack 204) is selected. The stack 204 extends in the Z-axis (e.g., into or out of the page). Spacers and source/drain electrodes may be formed over the edges of the stack 204 (the spacers are not seen in this view, as the edges are into or out of the page).

At 408, the intervening layers 404 are etched away, leaving surfaces of the channel layers 403 exposed. At 408, a view of the stage 408 is rotated by 90 degrees, with the Y-axis being the horizontal axis. Spacers 409 are formed on the edges of the stack 204. Source/drain electrodes 209 are formed for the different types of transistors in the stack 204, the Source/drain electrodes 209 being separated by the spacers 409 from the channel layers 403.

FIG. 4B illustrates stage 412, in which the dielectric layers 422 and various work function layers are formed to surround each of the channel layers 403. The stage 412 is a same view as stages 402, 406, and 408 (X-axis being horizontal, Z-axis being vertical). The channel layers 403 would become the transistor channels illustrated in FIG. 2 (e.g., the p-type channel 210 and the n-type channel 220; see FIG. 2). For ease of reference, the channel layers 403 are labeled 403_1, 403_2, 403_3, 403_4. The dielectric layers 422 are formed to surround each of the channel layers 403, respectively. In some examples, the dielectric layers 422 may be high-K dielectric. In some example, each of the dielectric layers 422 may surround most (e.g., more than half) of a surface of each of the channel layers 403. In some examples, each of the dielectric layer 422 is all around the surface of each of the channel layers 403 to from part of gate-all-around transistors. Referring to FIG. 2, the dielectric layers 422 would become the dielectric layers illustrated in FIG. 2 (e.g., the dielectric layers 212 for the p-type transistors 206-1 and 206-2; the dielectric layers 222 for the n-type transistors 208-1 and 208-2).

Work function layers 424 and 426, which would become a portion of the first set of work function layer 213 and the second set of work function layer 223 (FIG. 2), are formed over the dielectric layers 422. The work functional layers 424 may include TiN, and the work function layers 426 may include TaN. The work function layers 424 and 426 may be formed by atomic layer deposition. The work function layers 424 and 426 may surround most (e.g., more than half) of a surface of each of the dielectric layers 422 (and therefore, of a respective one of the channel layers 403). In some examples, the work function layers 424 and 426 are all around the surface of each of the dielectric layers 422 (and therefore, of a respective one of the channel layers 403) to from part of gate-all-around transistors. The work function layers 424 would become the TiN layers 214 and 224 of FIG. 2. The work function layers 426 would become the TaN layers 216 and 226 of FIG. 2.

FIG. 4C illustrates a stage 414 in which a mask layer 415 is formed to mask certain ones of the channel layers 403 and to mask the dielectric layers 422 and work function layers (e.g., layers 424 and 426) associated with the masked channel layers 403. The stage 414 is a same view as stages 402, 406, and 408 (X-axis being horizontal, Z-axis being vertical). The mask layer 415 is formed to mask the channel layers 403_3 and 403_4, which would become channels for n-type transistors 208_1 and 208_2, respectively. The mask layer 415 may include carbon-based organic flowable dielectric or anti-reflection coating material. In some examples, the mask layer 415 includes SiNx.

FIG. 4D illustrates a stage 416 in which additional work function layers 428 are formed to surround channel layers 403 not masked by the mask layer 415 in stage 414 (e.g., channel layers 403_1 and 403_2) and to surround the dielectric layers 422 and work function layers (e.g., layers 424 and 426) associated therewith. The stage 416 is a same view as stages 402, 406, and 408 (X-axis being horizontal, Z-axis being vertical). Additional work function layers 428 are formed around the channel layers 403_1 and 403_2 and not around the channel layers 403_3 and 403_4, which are masked by the mask layer 415. In some examples, the additional work function layers 428 may include TiN and would become the TiN layers 218 of FIG. 2.

FIG. 4E illustrates a stage 418 in which the mask layer 415 is removed, and addition work function layers 429 are formed around the channel layers 403_1, 403_2, 403_3, and 403_4 (and around the dielectric layers 422 and work function layers, e.g., layers 424, 426, and 428, associated therewith). The stage 418 is a same view as stages 402, 406, and 408 (X-axis being horizontal, Z-axis being vertical). In some examples, the additional work function layers 429 may include TiAl. In some examples, the additional work function layers 429 would become the TiAl layers shown in FIG. 2.

In such fashion, the first set of work function layer 213, including the work function layers 424 (e.g., the TiN layers 214), the work function layers 426 (e.g., the TaN layers 216), the work function layers 428 (e.g., the TiN layers 218), and the additional work function layers 429 (e.g., the TiAl layer 219) are formed around the channel layers 403_1 and 403_2. The first set of work function layer 213 renders to the channel layers 403_1 and 403_2 and have p-type conductivity. The channel layers 403_1 would become the p-type channel 210 and part of the p-type transistors 206_1 and 206_2.

The second set of work function layer 223, including the work function layers 424 (e.g., the TiN layers 214), the work function layers 426 (e.g., the TaN layers 216), and the additional work function layers 429 (e.g., the TiAl layer 219) are formed around the channel layers 403_3 and 403_4. The second set of work function layer 223 renders to the channel layers 403_3 and 403_4 and have n-type conductivity. The channel layers 403_3 would become the n-type channel 220 and part of the n-type transistors 208_1 and 208_2.

Gate electrodes may be formed over the first set of work function layer 213 and/or the second set of work function layer 223. Referring to FIG. 2, a gate electrode 230 may be formed over the p-type transistors 206_1, 206_2 and the n-type transistors 208_1, 208_2 in stack 204. Referring to FIG. 3, a gate electrode 302 (or gate electrode 304) may be formed for the p-type transistors 206_1 (or the p-type transistor 206_2). A gate electrode 306 (or gate electrode 308) may be formed for the n-type transistors 208_1 (or the n-type transistor 208_2). Insulation layers 303, 305, 307 may be formed to insulate the gate electrodes 302, 304, 306 and/or 308. For example, the gate electrode 304 for the p-type transistor 206_2 may be insulated from the gate electrode 306 for the n-type transistor 208_1 by the insulation layer 305.

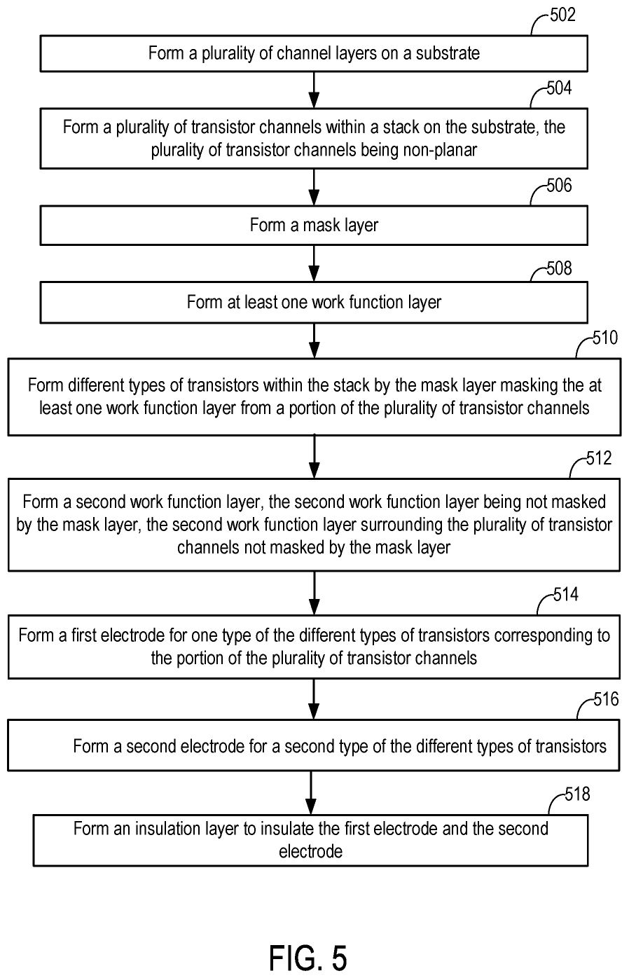

FIG. 5 illustrates a method to form different types of transistors within a stack, in accordance with certain aspects of the present disclosure. Operations shown may not be indicative of ordering of the operations. At 502, a plurality of channel layers is formed on a substrate. For example, referring to FIG. 4A at 402, multiple channel layers 403 are formed on the substrate 202. Intervening layers 404 are formed in alternate with the channel layers 403, to separate the channel layers 403. The channel layers 403 and/or the intervening layers 404 may be formed by epi growth. In some examples, the channel layers 403 may be Si, and/or the intervening layers 404 may be SiGe.

At 504, a plurality of channels is formed within a stack on the substrate, the plurality of channels being non-planar. See, for example, FIG. 4A at 404. The channel layers 403 and the intervening layers 404 of the stage 402 may be etched away at various locations alone the X-axis to form various stacks, including the stack 204 (see FIG. 2). The stack 204 includes multiple channel layers 403 in a vertical direction (Z-axis) above the substrate 202. The channel layers 403 and the intervening layers 404 of the stage 402 may be etched away at various locations alone the X-axis to form various stacks, including the stack 204. In such fashion, a width of the stack 204 (and therefore the transistors within the stack 204) is selected. The stack 204 extends in the Z-axis (e.g., into or out of the page). Spacers and source/drain electrodes may be formed over the edges of the stack 204 (the spacers are not seen in this view, as the edges are into or out of the page).

In some examples, the channel layers 403 are channels for non-planar transistors, such as nanosheet or nanowire transistors. The channel layers 403 may be nanosheet channels. For example, an X-Y area of the channel layers 403 may be greater than a height in the Z-axis of the channel layers 403.

At 506, a mask layer is formed. See, for example, FIG. 4C. The mask layer 415 is formed to mask the channel layers 403_3 and 403_4, which would become channels for n-type transistors 208_1 and 208_2, respectively. The mask layer 415 may include carbon-based organic flowable dielectric or anti-reflection coating material. In some examples, the mask layer 415 includes SiNx. Beyond flowable dielectric, in examples, dielectric may be formed to cover all elements, followed by top-down etch to remove the dielectric from certain areas.

At 508, at least one work function layer is form. See, for example, FIG. 4D. At least one work function layers 428 are formed to surround channel layers 403 not masked by the mask layer 415 in stage 414 (e.g., channel layers 403_1 and 403_2). The at least one work function layers 428 are formed around the channel layers 403_1 and 403_2 and not around the channel layers 403_3 and 403_4, which are masked by the mask layer 415. In some examples, the additional work function layers 428 may include TiN and would become the TiN layers 218 of FIG. 2.

At 510, different types of transistors are formed within the stack by the mask layer masking the at least one work function layer from a portion of the plurality of channels. At 512, a second work function layer is formed. The second work function layer is not masked by the mask layer. See, for example, FIG. 4E. The mask layer 415 is removed, and the second work function layers 429 are formed around the channel layers 403_1, 403_2, 403_3, and 403_4 (and around the dielectric layers 422 and work function layers, e.g., layers 424, 426, and 428, associated therewith). The second work function layers 429 are not masked by the mask layer 415, which is removed.

In such fashion, the first set of work function layer 213, including the work function layers 424 (e.g., the TiN layers 214), the work function layers 426 (e.g., the TaN layers 216), the work function layers 428 (e.g., the TiN layers 218), and the work function layers 429 (e.g., the TiAl layer 219) are formed around the channel layers 403_1 and 403_2. The first set of work function layer 213 renders to the channel layers 403_1 and 403_2 and have p-type conductivity. The channel layers 403_1 would become the p-type channel 210 and part of the p-type transistors 206_1 and 206_2.

The second set of work function layer 223, including the work function layers 424 (e.g., the TiN layers 214), the work function layers 426 (e.g., the TaN layers 216), and the work function layers 429 (e.g., the TiAl layer 219) are formed around the channel layers 403_3 and 403_4. The second set of work function layer 223 renders to the channel layers 403_3 and 403_4 and have n-type conductivity. The channel layers 403_3 would become the n-type channel 220 and part of the n-type transistors 208_1 and 208_2.

At 514, a first electrode for one type of the different types of transistors is formed. At 516, a second electrode for a second type of the different types of transistors is formed. At 518, an insulation layer is formed to insulate the first electrode and the second electrode is formed. See, for example, FIG. 3. A first electrode 304 is formed for the p-type transistor 206_2. A second electrode 306 for the n-type transistor 208_1 is formed. An insulation layer 305 is formed to insulate the first electrode 304 and the second electrode 306.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects. Unless specifically stated otherwise, the term “some” refers to one or more. Combinations such as “at least one of A, B, or C,” “one or more of A, B, or C,” “at least one of A, B, and C,” “one or more of A, B, and C,” and “A, B, C, or any combination thereof” include any combination of A, B, and/or C, and may include multiples of A, multiples of B, or multiples of C. Specifically, combinations such as “at least one of A, B, or C,” “one or more of A, B, or C,” “at least one of A, B, and C,” “one or more of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. The words “module,” “mechanism,” “element,” “device,” and the like may not be a substitute for the word “means.” As such, no claim element is to be construed as a means plus function unless the element is expressly recited using the phrase “means for.”

What is claimed is:

1. An apparatus, comprising:
a p-type transistor;
an n-type transistor, the p-type transistor and the n-type transistor being arranged in a stack vertically above a substrate, the p-type transistor and the n-type transistor being non-planar transistors,
wherein the p-type transistor comprising a p-type channel and a first set of work function layer, the first set of work function layer surrounding the p-type channel, the p-type channel being configured for p-type conductivity based on the first set of work function layer, and
wherein the n-type transistor comprising an n-type channel and a second set of work function layer, the second set of work function layer surrounding the n-type channel, the n-type channel being configured for n-type conductivity based on the second set of work function layer, the first set of work function layer and the second set of work function layer being different.

2. The apparatus of claim 1, wherein the p-type channel and the n-type channel are nanosheet channels.

3. The apparatus of claim 2, wherein the p-type transistor and the n-type transistor are gate-all-around transistors.

4. The apparatus of claim 1, further comprising one of a computing system, a mobile computing system, an Internet of Things device, a virtual reality system, or an augmented reality system, the device incorporating the p-type transistor and the n-type transistor.

5. The apparatus of claim 4, the first set of work function layer and the second set of work function layer share at least one common work function layer.

6. The apparatus of claim 5, further comprising
a first gate electrode for the p-type transistor, the first gate electrode surrounding the p-type channel; and
a second gate electrode for the n-type transistor, the second gate electrode surrounding the n-type channel, the first gate electrode and the second gate electrode being configured to operate independently.

7. A method to form different types of transistors within a stack, comprising:
forming a plurality of channel layers on a substrate;
forming a plurality of channels within a stack on the substrate, the plurality of channels being non-planar;
forming a mask layer;
forming at least one work function layer;
forming different types of transistors within the stack by the mask layer masking the at least one work function layer from a portion of the plurality of channels.

8. The method of claim 7, wherein the plurality of channels comprises nanosheet channels.

9. The method of claim 8, further comprising forming a second work function layer, the second work function layer being not masked by the mask layer.

10. The method of claim 9, further comprising
forming a first electrode for one type of the different types of transistors;
forming a second electrode for a second type of the different types of transistors; and
forming an insulation layer to insulate the first electrode and the second electrode.
